(19) United States
(12) Patent Application Publication
(10) Pub. No.: US 2007/0131168 A1
(43) Pub. Date: Jun. 14, 2007

(54) Gas Supplying unit and substrate processing apparatus

(76) Inventors: Hisashi Gomi, Nirasaki-Shi (JP); Tetsuya Saito, Nirasaki-Shi (JP); Takashi Kakegawa, Nirasaki-Shi (JP); Takahisa Mase, Nirasaki-Shi (JP); Makoto Koizumi, Nirasaki-Shi (JP); Kunihiro Tada, Nirasaki-Shi (JP); Satoshi Wakabayashi, Nirasaki-Shi (JP); Kensaku Narushima, Nirasaki-Shi (JP); Fang Cheng, Nirasaki-Shi (JP)

Correspondence Address: SMITH, GAMBRELL & RUSSELL, 1850 M STREET, N.W., SUITE 800, WASHINGTON, DC, 20036, US

(21) Appl. No.: 11/588,423

(22) Filed: Oct. 27, 2006

(30) Foreign Application Priority Data
Oct. 31, 2005 (JP) 2005-317496
Jan. 13, 2006 (JP) 2006-006697

(51) Int. Cl. C23C 16/00

(52) U.S. Cl. 118/715

(57) ABSTRACT

The invention relates to a gas supplying unit to be arranged to hermetically fit in an opening formed at a ceiling part of a processing container for conducting a process to a substrate. The gas supplying unit includes a plurality of nickel members. A large number of gas-supplying holes is formed at a lower surface of the gas supplying unit, a process gas is adapted to be supplied from the large number of gas-supplying holes into the processing container, and the plurality of nickel members is fixed to each other via an intermediate member for preventing sticking made of a material different from nickel.

### FIELD OF THE INVENTION

This invention relates to a gas supplying unit that supplies a process gas into a processing container from a large number of gas-supplying holes opposite to a substrate, in order to conduct a predetermined film-forming process to the substrate, and to a substrate processing apparatus including the gas supplying unit.

### BACKGROUND ART

The film-forming process is one of the semiconductor manufacturing processes. The film-forming process is generally conducted by, e.g., under a vacuum atmosphere, ionizing a process gas to form a plasma thereof or pyrolytically decomposing the process gas to activate the process gas, and depositing active species or reaction products on a surface of a substrate. There is a film-forming process in which a variety of gases are reacted on each other to form a film. For example, a thin film is formed of a metal such as Ti, Cu, and Ta, or a metal compound such as TiN, TiSi, and WSi, or an insulating material such as SiN and SiO₂.

An apparatus for conducing the film-forming process includes a stage for placing a substrate thereon, the stage being provided in a processing container which is a vacuum chamber, and a gas supplying unit provided in the processing container. Further, a heater, a plasma generating unit, and so on are provided for energizing the gas.

The gas supplying unit, which is generally referred to as a gas showerhead, is arranged to hermetically fit in an opening formed at a ceiling part of the processing container so as to be opposed to the stage. The gas showerhead is described in JP2002-327274A, for example. Specifically, as shown in FIG. 10, the gas showerhead includes: a base member 11 of a low and large cylindrical shape having a bottom, which fits in an opening formed at an upper part of a processing container; and a shower-plate 12 arranged on a lower side of a bottom surface of the base member 11. The base member 11 also functions as a separator for separating a vacuum atmosphere within the processing container from the atmospheric air. Thus, a flange portion 13 at an upper peripheral portion of the base member 11 and a peripheral portion 14 of the opening of the processing container are hermetically joined to each other via an O-ring 15 which is a ring-shaped sealing member made of resin.

A standing side wall is provided at a peripheral portion of the shower-plate 12. An upper edge of the side wall serves as a flange portion 12a. The flange portion 12a and a peripheral portion of a bottom part 15a of the base member 11 are joined to each other by a bolt 16. Two gas-supplying pipes 17a and 17b are connected to a center part of the base member 11. Gases supplied from the gas-supplying pipes 17a and 17b are respectively jetted through gas-supplying holes 18a and 18b which are separately formed in the shower-plate 12.

Nickel is used as a material for the gas showerhead. This is because: the nickel gas showerhead has a high corrosion resistance under a high temperature such as about 500° C.; a substrate is hardly suffered from a metal contamination from the nickel gas showerhead; and when a plasma process is conducted, the nickel gas showerhead also servers as an electrode with a high conductivity.

However, such a gas showerhead has the following disadvantages.

That is, depending on a kind of a process, a temperature of the showerhead may be raised to, e.g., 420° C. or higher, because of a high temperature of the processing atmosphere. Such a high temperature may cause “sticking” of the shower-plate 12 and the base member 11 at their joining portions. As described below, the experiment shows that a temperature of 450° C. or higher results in tight “sticking” phenomenon. That is, when the gas showerhead is used at a temperature of 420° C. or higher, there might be concern that the “sticking” phenomenon occurs, depending on manners of the usages and conditions of the joining surfaces. In a maintenance operation of the unit, the showerhead is disassembled for cleaning its inside space. However, when the sticking phenomenon has occurred, it is impossible to separate the shower-plate 12 and the base member 11 from each other, or a large force is required therefor. The sticking phenomenon is caused by that surface atoms of the nickel material diffuse through a joining interface, while the joining surfaces are stuck to each other by an anchor effect because of minute roughness in the joining surfaces. As described above, the sticking phenomenon makes difficult the maintenance operation. Alternatively, these members have to be periodically replaced. This replacement increases running costs, since the gas showerhead is made of a nickel material.

In addition, due to a large thermal conductivity of nickel, a heat quantity released through the side wall of the base member 11 is large. Thus, a calorific value of a heater provided in the gas showerhead should be increased. This is disadvantageous in that a power consumption is increased and the O-ring 15 is deteriorated because of the elevated temperature. Provision of a cooling mechanism can prevent the deterioration of the O-ring 15. However, since a large amount of heat is released from the base member 11, a large amount of consumption energy is required for cooling.

Moreover, the above gas showerhead has the following problem.

That is, in order to control a temperature of the gas showerhead, a sheet-like heater is arranged on an upper side of the bottom part of the base member 11. Also, a temperature detecting part having a thermocouple is arranged, with a distal end of the thermocouple being embedded in the bottom part of the base member 11. Based on a temperature value detected by the temperature detecting part, electric power to be supplied to the sheet heater can be controlled. The temperature detecting part is structured by inserting the thermocouple in a sheath metal filled with an insulating material. When a plasma process is conducted, there might be a possibility that a radiofrequency from the gas showerhead is applied between the sheath metal and the thermocouple to invite a dielectric breakdown. In order to prevent such a situation, an insulating material is sometimes provided between the base member 11 and the temperature detecting part. This, in turn, may make unstable the temperature control, because a heat generated by induction heating of the insulating material affects the detected temperature value.

### SUMMARY OF THE INVENTION

This invention is intended to solve the above problems. The object of this invention is to provide a gas supplying unit for supplying a process gas into a processing container, that is capable of preventing sticking of nickel members under a high temperature, so as to improve a maintenance property of the unit. Another object of the present invention is to provide a substrate processing apparatus including the gas supplying unit.

In order to achieve the above object, the present invention is a gas supplying unit to be arranged to hermetically fit in an opening formed at a ceiling part of a processing container for conducting a process to a substrate: the gas supplying unit comprising a plurality of nickel members, wherein a large number of gas-supplying holes is formed at a lower surface of the gas supplying unit, a process gas is adapted to be supplied from the large number of gas-supplying holes into the processing container, and the plurality of nickel members is fixed to each other via an intermediate member for preventing sticking made of a material different from nickel.

According to the present invention, between the joining surfaces of the plurality of nickel members, there is provided the intermediate member for preventing sticking made of a material different from nickel. Thus, the nickel portions are prevented from sticking to each other which might be caused by a high temperature. Since the gas showerhead can be easily disassembled for a maintenance operation, it is easy to clean and inspect an inside thereof. That is, replacement of the members can be avoided, which might be necessary when the maintenance operation cannot be performed.

Alternatively, the present invention is a gas supplying unit to be arranged to hermetically fit in an opening formed at a ceiling part of a processing container for conducting a process to a substrate: the gas supplying unit comprising a shower-plate mainly consisting of nickel, a large number of gas-supplying holes being formed in the shower-plate, and a base member provided above the shower-plate in order to form a process-gas diffusion space between the base member and the shower-plate, wherein a portion of the base member opposite to the shower-plate is made mainly of nickel, and an upper surface of a peripheral portion of the shower-plate and a lower surface of a peripheral portion of the base member are hermetically fixed to each other via an intermediate member for preventing sticking made of a material different from nickel.

According to the present invention, between the upper surface of a peripheral portion of the shower-plate and the lower surface of a peripheral portion of the base member, there is provided the intermediate member for preventing sticking made of a material different from nickel. Thus, the nickel members are prevented from sticking to each other which might be caused by a high temperature. Since the gas showerhead can be easily disassembled for a maintenance operation, it is easy to clean and inspect an inside thereof. That is, replacement of the members can be avoided, which might be necessary when the maintenance operation cannot be performed.

The term “nickel member” (or “nickel portion”) is not limited to a member (or portion) made of 100% nickel, but includes a member (or portion) made mainly of nickel.

Hastelloy or carbon are given as an example of a material of the intermediate member.

For example, the base member may be formed into a low and large cylindrical shape having a bottom, an upper end of a peripheral side wall of the base member may be hermetically attached to a peripheral portion of the opening of the processing container, and a bottom surface of the peripheral side wall of the base member may be hermetically fixed to a peripheral portion of the shower-plate. In this case, the peripheral side wall of the base member may be made of a material having a lower thermal conductivity than nickel. The material is preferably hastelloy. In addition, it is preferable that the base member may be provided with a reinforcement member made of a material having a lower thermal conductivity than nickel, in order to reinforce the peripheral side wall of the base member. Further, it is preferable that a coolant way be formed at an upper-end portion of the peripheral side wall of the base member.

In addition, preferably, a sheet-like heater is arranged on the base member via an insulating plate, the insulating plate is divided into a plurality of insulating-plate elements in a planar direction thereof, and the sheet-like heater is divided into a plurality of sheet-heater elements in a planar direction thereof.

In addition, for example, the process gas may include a first gas and a second gas, the first gas and the second gas may be capable of reacting on each other in order to generate a film-forming component, the first gas and the second gas may be mixed in advance to become a mixed gas, and the mixed gas may be supplied into the processing container as a process gas (so-called pre-mix type of gas supply).

In addition, the present invention is a substrate processing apparatus comprising a processing container whose ceiling part has an opening, a stage provided in the processing container, for placing a substrate thereon, a gas discharging unit for discharging a gas from the processing container, and a gas supplying unit arranged to hermetically fit in the opening of the ceiling part of the processing container, wherein the gas supplying unit comprises a plurality of nickel members, a large number of gas-supplying holes is formed at a lower surface of the gas supplying unit, a process gas is adapted to be supplied from the large number of gas-supplying holes into the processing container, and the plurality of nickel members is fixed to each other via an intermediate member for preventing sticking made of a material different from nickel.

Alternatively, the present invention is a substrate processing apparatus comprising a processing container whose ceiling part has an opening, a stage provided in the processing container, for placing a substrate thereon, a gas discharging unit for discharging a gas from the processing container, and a gas supplying unit arranged to hermetically fit in the opening of the ceiling part of the processing container, wherein the gas supplying unit comprises: a shower-plate mainly consisting of nickel, a large number of gas-supplying holes being formed in the shower-plate; and a base member provided above the shower-plate in order to form a process-gas diffusion space between the base member and the shower-plate, a portion of the base member opposite to the shower-plate is made mainly of nickel, and an upper surface of a peripheral portion of the shower-plate and a lower surface of a peripheral portion of the base member are hermetically fixed to each other via an intermediate member for preventing sticking made of a material different from nickel.

In this case, for example, the base member may be formed into a low and large cylindrical shape having a bottom, an upper end of a peripheral side wall of the base member may be hermetically attached to a peripheral portion of the opening of the processing container, and a bottom surface of the peripheral side wall of the base member may be hermetically fixed to a peripheral portion of the shower-plate.

In this case, preferably, the upper end of the peripheral side wall of the base member may be hermetically attached to the peripheral portion of the opening of the processing container via an upper-side insulating member made of alumina for radio-frequency insulation, and a lower-side insulating member made of quartz for radio-frequency insulation may be provided below the upper-side insulating member so as to cover a portion of the processing container located laterally adjacent to the peripheral side wall of the base member.

Alternatively, preferably, the upper end of the peripheral side wall of the base member may be hermetically attached to the peripheral portion of the opening of the processing container via a sealing member made of resin.

In addition, for example, the substrate processing apparatus may further comprise a first temperature-controlling unit provided in the stage for heating the substrate, a second temperature-controlling unit provided in the gas supplying unit for controlling a temperature of a surface of the gas supplying unit in contact with the process gas, and a controlling part that controls the first temperature-controlling unit and the second temperature-controlling unit, wherein a gas supplying control is adapted to be conducted in such a manner that: a titanium chloride gas and a hydrogen gas are supplied as a process gas from the gas supplying unit into the processing container in order to generate a titanium film on the substrate, and then an ammonia gas is supplied from the gas supplying unit into the processing container in order to nitride the titanium film on the substrate, and the controlling part is adapted to control the second temperature-controlling unit in such a manner that: a temperature of the surface of the gas supplying unit in contact with the process gas is lower than a temperature at which nickel and ammonia react to generate a solid product, and is within a decomposition temperature zone of TiClx (x=1, 2 or 3).

In this case, for example, the controlling part may be adapted to control the second temperature-controlling unit in such a manner that a temperature of the surface of the gas supplying unit in contact with the process gas is 400 to 450° C.

Alternatively, for example, the controlling part may be adapted to control the first temperature-controlling unit in such a manner that a temperature of the substrate is increased to 450 to 600° C., and the controlling part may be adapted to control the second temperature-controlling unit in such a manner that a temperature of the second temperature-controlling unit is 180 to 475° C. depending on the temperature of the substrate.

### BRIEF DESCRIPTION OF THE DRAWINGS

FIG. 1 is a schematic sectional view of a film-forming apparatus including a gas supplying unit according to an embodiment of the present invention;

FIG. 2 is a schematic sectional view showing the gas supplying unit of FIG. 1 in details;

FIG. 3 is an exploded sectional view showing a part of the gas supplying unit of FIG. 1;

FIG. 4 is an exploded perspective view showing a part of the gas supplying unit of FIG. 1;

FIG. 5 is an enlarged sectional view showing a base member and a temperature-controlling unit of the gas supplying unit of FIG. 1;

FIG. 6 is a schematic sectional view showing a state in which a temperature detecting part used in the gas supplying unit of FIG. 1 is embedded in a bottom part of a base plate;

FIG. 7 is a sectional view showing a structure of a distal end of the temperature detecting part of FIG. 6;

FIG. 8 is a view of assistance in explaining a relationship between generation of a titanium compound and temperature;

FIG. 9 is a structural view showing a temperature controlling system in the gas supplying unit of FIG. 1; and

FIG. 10 is a schematic sectional view showing a conventional gas supplying unit.

### DESCRIPTION OF THE PREFERRED EMBODIMENT

An embodiment of the present invention will be described below. The gas supplying unit in this embodiment is included in a film-forming apparatus that forms a film by a plasma CVD process.

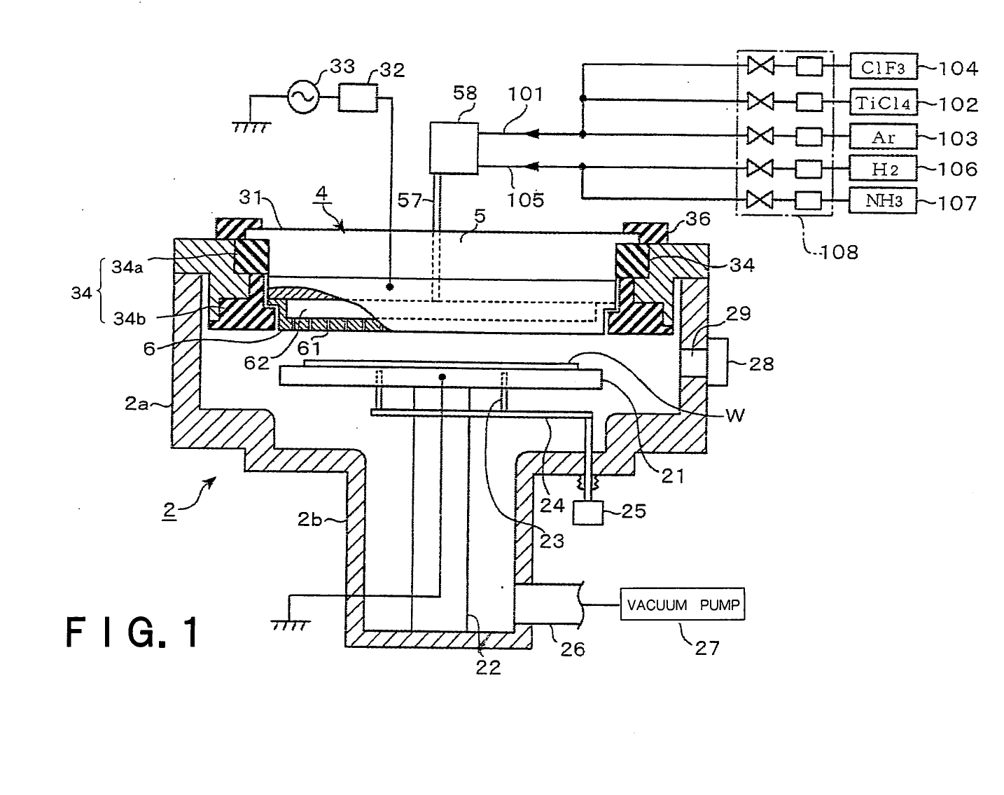

The general structure of the film-forming apparatus is described with reference to the schematic sectional view of FIG. 1. In FIG. 1, a processing container 2 is a vacuum chamber made of, e.g., aluminum. An upper part of the processing container 2 is a cylindrical part 2a of a larger diameter, and a lower part of the processing container 2 is a cylindrical part 2b of a smaller diameter. The cylindrical parts 2a and 2b are continuously connected to form a mushroom shape in general. A heating mechanism, not shown, is provided for heating an inner wall of the processing container 2. A stage 21 is arranged in the processing container 2 for horizontally placing thereon a substrate such as a semiconductor wafer (hereinafter referred to as “wafer”) W. The stage 21 is supported on a bottom part of the smaller-diameter part 2b via a support member 22.

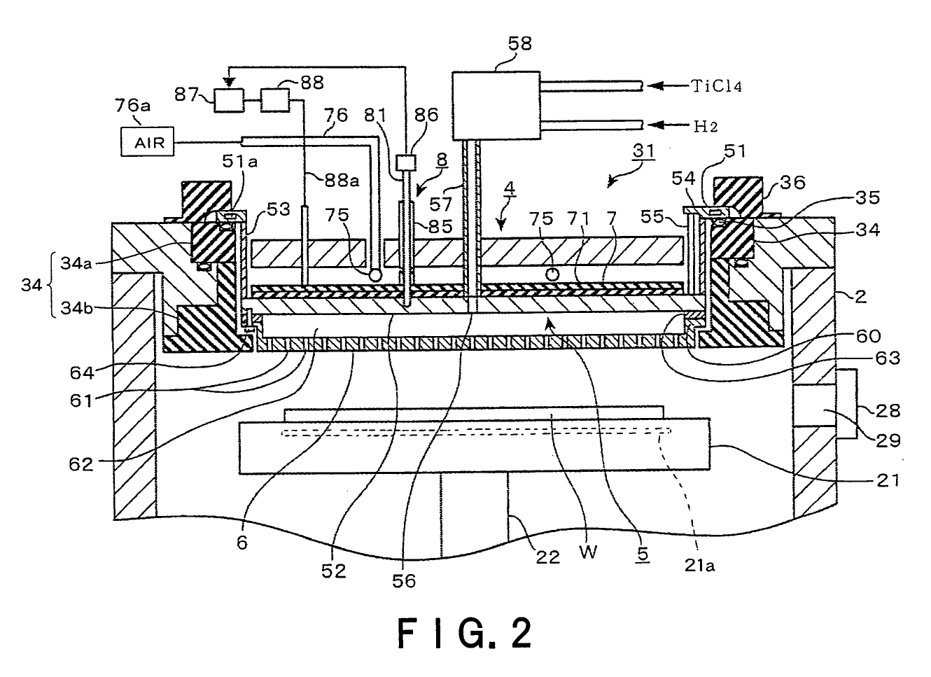

A heater 21a (see, FIG. 2) as means for controlling a temperature of the wafer W is arranged in the stage 21. A conductive member (not shown) serving as a lower electrode, which is described below, is arranged in the stage 21. A not-shown electrostatic chuck for electrostatically absorbing the wafer W is arranged when needed. A plurality of, e.g., three support pins 23 for supporting and vertically moving the wafer W is arranged in the stage 21. The support pins 23 are capable of projecting and retracting from a surface of the stage 21. The support pins 23 are connected to an elevating mechanism 25 disposed outside the processing container 2 via a support member 24. One end of an discharging pipe 26 is connected to a bottom part of the processing container 2. A vacuum pump 27 as vacuum discharging means is connected to the other end of the discharging pipe 26. A feed port 29, which is opened and closed by a gate valve 28, is formed in a side wall of the larger-diameter part 2a of the processing container 2.

An opening 31 is formed at a ceiling part of the processing container 2. A gas showerhead 4 as a gas supplying unit in this embodiment is arranged in such a manner that the gas showerhead 4 hermetically fits in the opening 31, and is opposed to the stage 21. The gas showerhead 4 and the stage 21 serve also as an upper electrode and a lower electrode, respectively. That is, the gas showerhead 4 is connected to a radiofrequency power source 33 through a matching unit 32, and the stage 21 as the lower electrode is grounded. Although a wiring diagram is schematically illustrated in FIG. 1, the stage 21 is actually, electrically connected to the processing container 2, and is grounded through an upper part of the processing container 2 and a matching box, not shown. A radiofrequency conductive path is formed to enclose the processing space.

As shown in FIG. 2, the gas showerhead 4 includes a base member 5 as an upper part and a shower-plate 6 as a lower part. The base member 5 is formed into a low and large cylindrical shape having a bottom, with its upper surface being opened while its lower surface being closed (in other words, into a circular plate with its peripheral vertically-standing wall). An upper end of the peripheral side wall of the cylindrical part is bent outward to form a flange portion 51. An insulating member 34 is disposed at an inner peripheral portion of the opening 31 of the processing container 2. The insulating member 34 prevents passage of electricity (of radiofrequency) from the gas showerhead 4 as the upper electrode to a metal body part of the processing container 2. The flange portion 51 of the base member 5 is fixed on an upper surface of the insulating member 34 by a screw, not shown. In more detail, an O-ring 35, which is a resin sealing member of a ring shape, is sealingly fitted in a ring-shaped groove formed in the upper surface of the insulating member 34, and a lower surface of the flange portion 51 and the upper surface of the insulating member 34 are hermetically secured to each other via the O-ring 35. The flange portion 51 is secured on the insulating material 34 by the screw at a location outside the O-ring 35. A pushing ring member 36 made of an insulating material is disposed to urge the flange portion 51 onto the insulating member 34. In this manner, the base member 5 hermetically fits in the opening 31.

The insulating member 34 is of a two-layer structure including an upper part (upper insulating member) 34a and a lower part (lower insulating member) 34b. A material of the upper part 34a is alumina, while a material of the lower part 34b is quartz. The lower part 34b is provided so as to cover a portion of the processing container 2 located laterally adjacent to the base member 5. The reason for adopting the two-layer structure is as follows: That is, since the lower part 34b covering the showerhead 4 is made of quartz having a low relative dielectric constant, a radiofrequency impedance between the showerhead 4 and a wall of the processing container 2 can be increased as much as possible. Thus, leakage of a radiofrequency from between the showerhead 4 and the processing container 2 can be lowered, which decreases loss of power and leakage of noises, so that abnormal electric discharge hardly occurs. Meanwhile, since quartz is difficult to be processed, the upper part 34a is made of alumina which is easy to be processed, although its relative dielectric constant is high. This makes it easier to bore a threaded opening used for securing the flange portion 51 of the showerhead 4. That is, the upper part 34a is formed over a range in which the threaded opening is bored. It is preferable that a lower end position of the upper part 34a, i.e., an upper end position of the lower part 34b, stand as high as possible, so as to enlarge an area of the lower part 34b covering the showerhead 4.

The flange portion 51 and a bottom part 52 of the base member 5 are formed of a nickel member. Herein, the term “nickel member” includes both a member made of 100% nickel, and a member which is made mainly of nickel but includes some components other than nickel. A side wall 53 of the base member 5 is made of a material having a lower thermal conductivity than the nickel member. For example, hastelloy is used in this example. The side wall 53 may conduct upward heat, which is generated for heating a part of the gas showerhead 4 on a side of the processing atmosphere (on a side of the process gas). In order to prevent this heat conduction, a thickness of the side wall 53 is reduced to, e.g., 1 mm. Herein, hastelloy has a high strength in addition to a low thermal conductivity. Thus, the thickness of the side wall 53 can be reduced, with retaining a strength equivalent to the nickel member. However, due to the vacuum atmosphere within the processing container 2, a significantly large force is applied to the side wall 53. Thus, the side wall 53 is reinforced to prevent a deformation thereof.

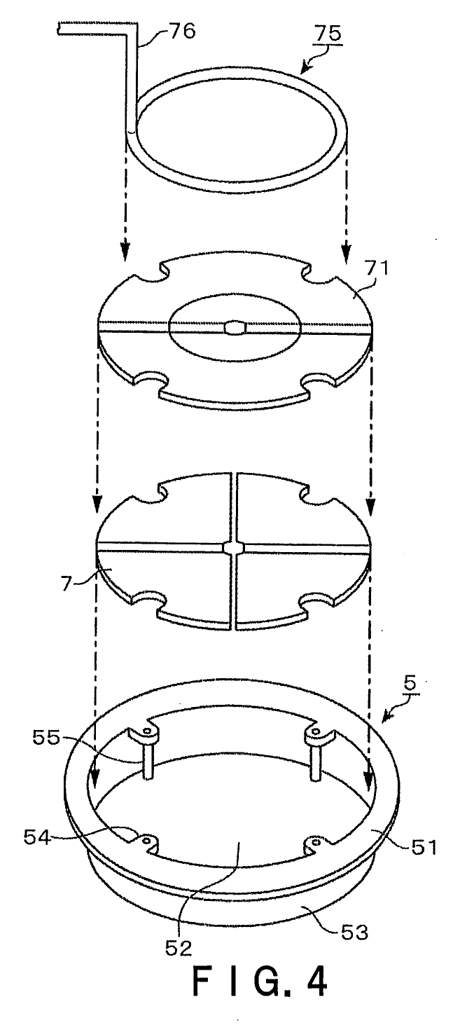

That is, as shown in the exploded perspective view of FIG. 4, a plurality of, e.g., four projections 54 projecting inward the base member 5 is circumferentially provided at equal spaced intervals on an inner periphery of an upper end of the base member 5. Struts 55 as reinforcing members such as reinforcing pipes are arranged so as to connect the respective projections 54 to the bottom part 52 of the base member 5. The projections 54 and the struts 55 may conduct heat upward from below. Thus, in this example, the projections 54 and the struts 55 are made of a material having a lower thermal conductivity than the nickel member, such as hastelloy. In order to combine a member made of hastelloy with the nickel member, the members are brazed, for example.

An air-cooling way 51a as a coolant way serving as a cooling mechanism is formed in the flange portion 51 to prevent a temperature elevation of the O-ring 35.

Next, the shower-plate 6, which is the lower part of the gas showerhead 4, is described.

The shower-plate 6 has a circular plate part at a position opposing the stage 21. A peripheral portion surrounding the plate part stands, and an upper part of the standing periphery is bent outward to form a flange portion 60. A portion to be screwed is inwardly cut out from an outer circumference.

By fixing the shower-plate 6 to the base member 5, a gas diffusion space 62 is formed therebetween. A large number of gas-supplying holes 61 for supplying a process gas into the processing container 2 is drilled in the shower-plate 6. The gas-supplying holes 61 are in communication with the diffusion space 62.

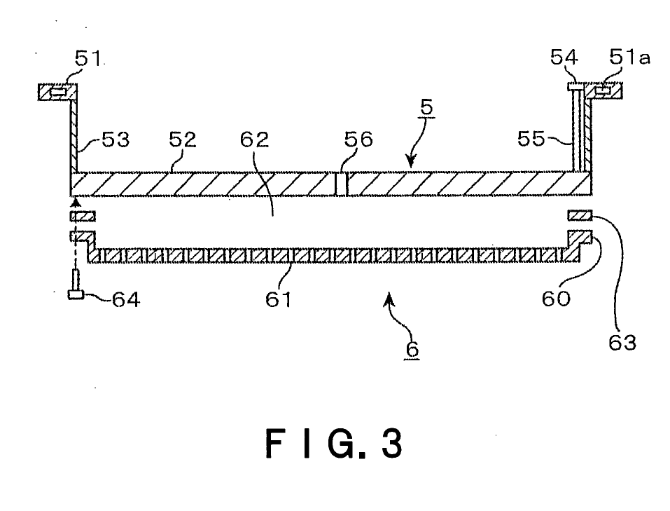

The shower-plate 6 is formed of the above-described nickel member. As shown in FIGS. 2 and 3, an upper surface of the flange portion 60 and a lower surface of a peripheral portion of the bottom part 52 of the base plate (base member) 5 are fixed to each other by screws 64, with a ring-shaped intermediate member 63 being interposed therebetween. A material of the intermediate member 63 is different from the nickel member in order to prevent “sticking” of the nickel members. Specifically, a material which will not cause a metal contamination is preferred. Hastelloy or carbon can be taken for instance. In this example, the intermediate member 63 is made of hastelloy and has a thickness of 2.6 mm.

The gas showerhead 4 in this embodiment supplies a mixed gas as a process gas into the processing container 2. The mixed gas is formed in advance by mixing a plurality of gases. That is, the gas supplying unit in this embodiment is of so-called pre-mix type. As shown in FIG. 2, a gas feed port 56 for supplying a process gas (mixed gas) is drilled in a center part of the bottom part 52 of the base member 5. A gas feed pipe 57 is extended upward from the gas feed port 56. A gas mixing part 58 is connected to an upstream end of the gas feed pipe 57. The gas mixing part 58 is connected to, e.g., a TiCl₄ gas source 102, an Ar gas source 103, and a CIF₃ gas source 104, via gas supplying channels 101. The gas mixing part 58 is also connected to, e.g., an H₂ gas source 106 and an NH₃ gas source 107, via gas supplying channels 105. A part 108 encircled with chain lines depicts a group of gas supplying instruments, such as valves and massflow controllers, disposed on the respective gas supplying channels.

A temperature adjusting mechanism is arranged above the bottom part 52 of the base member 5, for adjusting a temperature of the shower-plate 6 facing the gas diffusion space 62 and the processing atmosphere. The temperature adjusting mechanism is described with reference to FIG. 4.

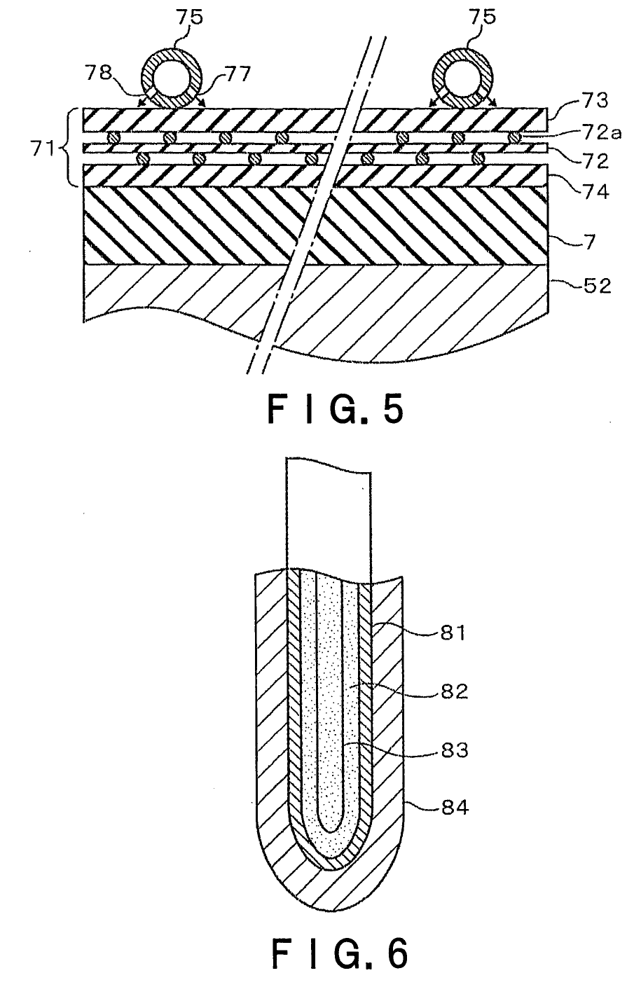

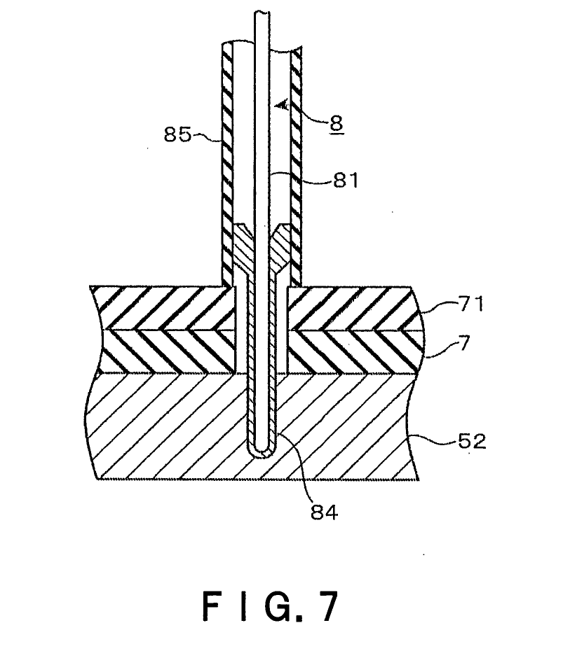

An insulating plate 7 with a thickness of, e.g., 4 mm made of an insulating member such as aluminum nitride (AlN) is disposed on an upper surface of the bottom part 52. A sheet-like heater 71 is placed on the insulating plate 7. From the standpoint of a maintenance property, the insulating plate 7 and the heater 71 are preferably divided into a plurality of elements in a planar direction thereof. In this example, there are employed the insulating plate 7 divided into four elements and the heater 71 divided into two elements. As shown in FIG. 5, the sheet heater 71 in this example is of a sandwich structure. Namely, protective plates 73 and 74 made of mica as an insulating material sandwich therebetween a core plate 72 made of mica around which a resistive heating line 72a winds.

With a view to stabilizing a temperature of the shower-plate 6, it is preferable that a center of the base member 5 and a center of the heater 71 correspond to each other, and that a surface area of the heater 71 relative to a surface area of the base member 5 be 80% or more.

By interposing the insulating plate 7 made of AlN between the base member 5 and the heater 71, when a plasma process is conducted, the influence given on the heater 71 by the radiofrequency flowing through the base member 5 can be reduced. Thus, dielectric breakdown of mica of the heater 71 can be prevented. Moreover, since AlN has a high thermal conductivity, it can be expected that heat is efficiently transmitted from the heater 71 to the base member 5.

Further, as shown in FIGS. 2, 4, and 5, an air-cooling pipe 75 as a cooling mechanism is disposed on the upper surface of the heater 71. The air-cooling pipe 75 includes an annular ring portion, and an airline 76 standing from the ring portion. A proximal end of the airline 76 is connected to an air source 76a. As shown in FIG. 5, a large number of blowing holes 77 and 78 for blowing an air of, e.g., normal temperature is formed at spaced intervals in a lower side surface of the ring portion of the air-cooling pipe 75 in a length direction (circumferential direction) thereof. The blowing holes 77 are oriented inward at an angle of 45° relative to the vertical line, and the blowing holes 78 are oriented outward at an angle of 45° relative to the vertical line. A cooling operation by the air blown from the blowing holes 77 and 78 is performed between a film-forming process and a cleaning process, so as to rapidly cool the bottom part 52 of the base member 5. Besides, the cooling operation can be performed when a detected temperature of the bottom part 52 exceeds a set temperature because of radiant heat from the stage 21 during a process such as a pre-coating process. The air blown from the blowing holes 77 cools a center region of the heater 71, and the air blown from the blowing holes 78 cools a peripheral region of the heater 71. A size (diameter) of the ring portion of the air-cooling pipe 75 can be suitably decided based on experiments or the like.

As shown in FIG. 2, a distal end of a temperature detecting part 8 having a thermocouple is embedded in the bottom part 52 of the base member 5. As shown in FIG. 6, the temperature detecting part 8 includes a sheath metal 81 filled with magnesia (magnesium oxide) 82 as an insulating material, and a thermocouple 83 inserted in the sheath metal 81. A distal end of the sheath metal 81 is covered with a protective cap 84 made of alumina as an insulating material. The temperature detecting part 8 passes through respective openings formed in the heater 71, the insulating plate 7, and the bottom part 52 of the base member 5 to be embedded in the bottom part 52 (see, FIG. 2). A protective tube 85 stands from the heater 71 to receive therein parts of the sheath metal 81 and the protective cap 84. An upper part of the sheath metal 81 is fixed on the base member 5 via a fixing member 86 (see, FIG. 2). In FIG. 2, the reference numbers 87 and 88 depict a controlling part and a power source part, respectively. The controlling part 87 performs a temperature control by adjusting a power supplied from the power source part 88 to the heater 71, based on a detected temperature value detected by the temperature detecting part 8. The reference number 88a depicts a feeder wire.

If the sheath metal 81 contacts the base member 5 (bottom part 52), a radiofrequency flowing through the base member 5 is applied between the sheath metal 81 and the thermocouple 83, so that the magnesia (magnesium oxide) is dielectrically broken. However, due to the provision of the protective cap 84, such a dielectric breakdown can be avoided. The protective cap 84 may be made of AlN. However, because of its high dielectric constant, AlN may have a large amount of heat generated by induction heating. When a temperature is elevated by the amount of heat, the elevation may have an adverse effect on the detected temperature value, which may make unstable the temperature control. For this reason, a preferable material of the protective cap 84 is alumina. Since alumina has a low dielectric constant, an amount of heat generated by induction heating is also small. As a result, accurate and stable temperature control can be achieved.

Now, effects of the above-described embodiment will be described. Given herein as an example to describe the process is a case in which a Ti film is formed on a surface of a wafer W. The interior of the processing container 2 is currently cleaned, and the process is going to be conducted.

Before the wafer W is processed, the processing container 2 is subjected to a pre-coating process. The pre-coating process is conducted for forming, on surfaces of members to be exposed to a processing atmosphere (process gas), a film which is the same kind as a film to be formed on the wafer W. In this example, the pre-coating process is a Ti-film forming process.

To be specific, a mixed gas of TiCl₄ gas and an Ar gas is supplied as a first gas from the gas supplying sources 102 and 103 into the gas mixing part 58 via the gas supplying channels 101. An H₂ gas as a second gas is supplied from the gas supplying source 106 into the gas mixing part 58 via the gas supplying channel 105. These gases are mixed in the gas mixing part 58. The mixed gas is discharged to the diffusion space 62 in the gas showerhead 4 via the gas inlet pipe 57, and is diffused in the diffusion space 62. Then, the gas is supplied into the processing container 2 via the gas supplying-holes 61 of the shower-plate 6.

Meanwhile, the interior of the processing container 2 is evacuated to create a vacuum therein by the vacuum pump 27. That is, a pressure adjusting valve, not shown, disposed on the discharging pipe 26 is adjusted to adjust a pressure in the processing container 2 to a set pressure. A radiofrequency power is applied by the radiofrequency power source 33 between the gas showerhead 4 as an upper electrode and the stage 21 as a lower electrode. Thus, the process gas is made plasma, and TiCl₄ is reduced by H₂. In this manner, a Ti film is deposited (pre-coat film is formed) on the surfaces of the members in contact with the processing atmosphere, more precisely, the upper surface of the stage 21 and the lower surface of the shower-plate 6. At this time, HCl as a reaction byproduct is discharged along with a non-reacted gas.

In order to enhance a film quality of the pre-coat film, i.e., to make the film dense and difficult to be peeled, a temperature of the shower-plate 6 has to be set at a predetermined set temperature of, e.g., 420° C. The temperature of the stage 21 is set at 650° C., for example, and a temperature of the gas showerhead 4 is raised by radiant heat from the stage 21. As described above, since a part (such as side wall 53) of the gas showerhead 4 is made of hastelloy to prevent escape of heat, a large amount of heat is stored in the shower-plate 6 and the bottom part 52 of the base member 5, which may undesirably increase the temperature of the shower-plate 6 beyond the set temperature of 420° C. Therefore, in order to cool the gas showerhead 4, air is blown from the air-cooling pipe 75 arranged above the bottom part 52.

In this cooling operation, the temperature of the gas showerhead 4 is controlled in the following manner. That is, air is constantly blown to keep the temperature of the overall gas showerhead 4 lower than the set temperature of 420° C. Under this state, the heater 71 is operated to heat the gas showerhead 4 so as to conform a detected temperature value to the set temperature value. When the air-blowing operation is used for adjusting a temperature of the gas showerhead 4 to conform to the set temperature, it is difficult to stably control the temperature, because of its slow change of endothermic amount. However, since the heater 71 is used to conform the temperature of the gas showerhead 4 to the set temperature, the temperature control thereof can be stably carried out. Consequently, an excellent pre-coating process can be realized.

After the pre-coating process is completed, as shown in FIG. 1, the wafer W as a substrate is loaded into the processing container 2 by a conveying arm, not shown, through the feed port 29 opened by the gate valve 28. The wafer W is delivered to the stage 21 by the support pins 23. Then, the gate valve 28 is closed. In accordance with the same procedures as those to form the pre-coat film, the film forming process is conducted. Therefore, a Ti film is formed on the wafer W. During the film forming process, the temperature of the gas showerhead 4 is controlled in a manner similar to the above pre-coating process.

Following thereto, the supply of the TiCl₄ gas as the first gas and the H₂ gas as the second gas is stopped, and the supply of an NH₃ (ammonia) gas is started. The NH₃ gas is discharged into the gas diffusion space 62, and the diffused NH₃ gas is discharged into the process space through the gas-supplying holes 61. Similarly to the above, a radiofrequency power is supplied to the process space. Thus, a surface of the Ti film already formed on the wafer W is nitrided by active species of NH₃. After the surface is nitrided, the supply of the radiofrequency power and the supply of the NH₃ gas are stopped. Subsequently, the wafer W is unloaded from the processing container 2 in accordance with the procedures reverse to the loading operation.

After the predetermined number of wafers W are subjected to the film forming process, a cleaning process is conducted. The cleaning process is conducted by supplying a CIF₃ gas, which is not made plasma, from the showerhead 4 into the processing container 2 via the gas supplying channel 101. The temperature of the shower-plate 6 has to be set at about 200 to 250° C. Since the air is constantly blown from the air-cooling pipe 75, the gas showerhead 4 is rapidly cooled by a cooling operation of the blowing air when the heater 71 is turned off. Thus, it is possible to promptly put the cleaning operation into practice.

In the above embodiment, the ring-shaped intermediate member 63 made of hastelloy is disposed between the upper surface of the peripheral portion of the shower-plate 6 and the lower surface of the peripheral portion of the base member 5, in order to prevent sticking of the shower-plate 6 and the base member 5. Thus, the sticking phenomenon of the nickel members, which might be caused by a high temperature, can be prevented. Since the gas showerhead 4 can be easily disassembled for a maintenance operation thereof, the operator can clean or inspect the inside of the gas showerhead without any trouble. That is, replacement of some members can be avoided, which might be necessary if the maintenance operation cannot be performed. This restrains increase in running costs.

As described above, by forming the side wall 53 and the struts 55 as reinforcing members of the base member 5 out of hastelloy having a low thermal conductivity, escape of heat outward from the bottom part 52 of the base member 5 can be reduced. Thus, the shower-plate 6 can be efficiently heated, so that the power consumption can be saved. Owing to a high strength of hastelloy, a thickness of the side wall 53 can be reduced as thin as 1 mm. This also can moderate the escape of heat from the bottom part 52 of the base member 5 to outside, and save the power consumption. On the other hand, it is necessary to consider an adverse effect of the above structure. That is, a large amount of heat is stored in the shower-plate 6, so that a temperature of the gas showerhead 4 undesirably may exceed the set temperature. However, since the temperature is controlled: by constantly blowing air to maintain the same slightly lower than the set temperature and then by using the heater 71 to correctly adjust the temperature, the temperature can be suitably controlled. The temperature control is conducted by a controlling part 9 (see, FIG. 9). That is, the controlling part 9 controls instruments for the air-blowing operation as well as the heater 71.

Further, as described above, since the heater 71 is placed on the insulating plate 7 made of AlN, a dielectric breakdown of the heater 71 will not occur. Furthermore, since the distal end of the temperature detecting part 8 is covered with the alumina cap 84, a stable temperature control can be practiced.

Next, results of experiments conducted for confirming an effect of the intermediate member are described below.

In these experiments, square blocks made of nickel members of 34 mm in length and 16 mm in width were used. The blocks were stacked and fastened to each other by a bolt with a torque of about 3 to 5 N-m. These blocks were heated for fifty hours at temperatures of 450° C. and 500° C., respectively. On the other hand, the blocks with a hastelloy laminate having a thickness of 0.15 mm being interposed therebetween were similarly heated. In the respective experiments, a plurality of samples was prepared and heated.

Experiment results were as follows: Among the directly joined nickel members which had been heated at the temperature of 450° C., some samples required a tensile stress as large as 200 Kgf for separating the nickel members. On the other hand, among the joined nickel members with the intermediate member which had been heated at the temperature of 450° C., some samples exhibited no sticking phenomenon. Although a few samples exhibited sticking phenomenon, it was easy to manually separate the nickel members. Among the joined nickel members with the intermediate member which had been heated at the temperature of 500° C., a few samples at most exhibited negligible sticking phenomenon.

Accordingly, it was confirmed that the sticking phenomenon of the nickel members which is caused by a high temperature can be effectively prevented by interposing the intermediate member between the nickel members.

When the film forming process is conducted to the wafer W by using the above film forming apparatus as a substrate processing apparatus, it is general to prepare a plurality of set temperatures of the wafer W, depending on a kind of completed integrated circuit or a part on which a film is formed. When a plurality of process steps is continuously performed, for example, when a Ti film is formed by using the TiCl₄ gas and the H₂ gas, and the Ti film is subsequently nitrided by the NH₃ gas, attention has to be paid to a temperature of a part in contact with the processing atmosphere of the gas showerhead 4 (this temperature is referred to as “temperature of the shower-plate 6”). At first, in the Ti-film forming process, the TiCl₄ gas is decomposed in plasma, and a decomposed product TiClx of low order (x=1, 2 or 3) is generated. The TiClx adheres to a part of a low temperature in the processing container, and makes unstable the film forming process. In particular, when the TiClx adheres to the shower-plate 6 in contact with the plasma and remains thereon in an unstable state, there is a possibility that unnecessary Ti atoms are supplied to the plasma during the Ti-film forming process so as to significantly deteriorate reproductivity of the Ti-film forming process. In order to avoid this, it is necessary to maintain the temperature of the shower-plate 6 at a temperature high enough to further decompose the adhered TiClx into a Ti film of a stable state. The decomposition (stabilization) temperature of the TiClx is more than about 400° C., although it depends on the nitride process succeeding the Ti-film forming process.

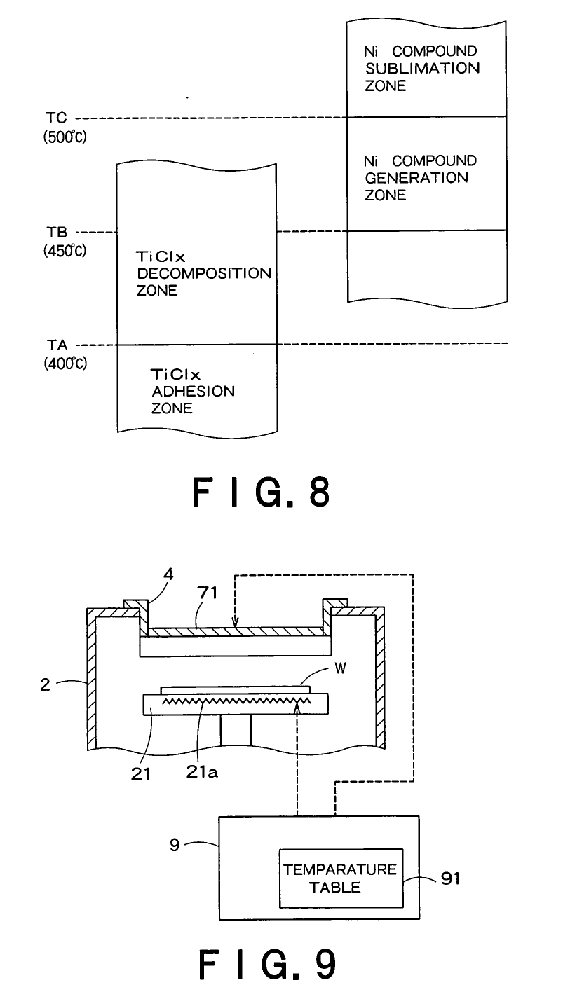

At a temperature around 450° C., nickel forming the gas showerhead 4 and the NH₃ gas are reacted to generate a nickel compound which is a solid product. The nickel compound is sublimated at a temperature around 500° C. Thus, the nickel compound adheres to a part whose temperature is within this range. FIG. 8 shows a relationship between the temperature and the compound, in which a decomposition temperature of TiClx, a generation temperature of the nickel compound, and a sublimation temperature of the nickel compound are represented by TA, TB, and TC, respectively.

Based on the reason as described above, employment of three set temperatures of the wafer W, i.e., the set temperatures of 450° C., 550° C., and 600° C. is contemplated by the inventors of the present invention. When the nickel compound is generated to adhere to the shower-plate 6, the nickel compound may peel therefrom to cause a particle contamination. Thus, the temperature of the shower-plate 6 is required to be lower than the generation temperature TB of the nickel compound, or higher than the sublimation temperature TC thereof. In this case, from the standpoint of a safe and reliable system that does not allow generation of the nickel compound itself, the temperature of the shower-plate 6 is preferred to be lower than the generation temperature TB of the nickel compound. Additionally, when a temperature of the wafer W is lower than the sublimation temperature TC of the nickel compound, a temperature of the shower-plate 6 must be inevitably lower than TB. This is because, even when the nickel compound is sublimated by increasing the temperature of the shower-plate 6 higher than TC, the sublimate may adhere to the surface of the wafer W.

An example of a process recipe contemplated by the inventors is described. The process recipe may be stored in a storage unit 91 in the controlling part 9 as a temperature table (see, FIG. 9). Based on the fact that the a decomposition temperature zone of TiClx is 400° C. or more, and that a generation temperature of the nickel compound is higher than 450° C., a temperature of the wafer, a temperature of the shower-plate 6 (shower temperature), and a temperature of the heater 71 can be set as follows:

| Wafer Temperature | Shower | Temperature of Heater 71 |
|---|---|---|
| (° C.) | Temperature (° C.) | (° C.) |
| 450 | 400 | 400 |
| 450 | 450 | 475 |
| 550 | 400 | 320 |
| 550 | 450 | 410 |
| 600 | 400 | 180 |
| 600 | 450 | 300 |

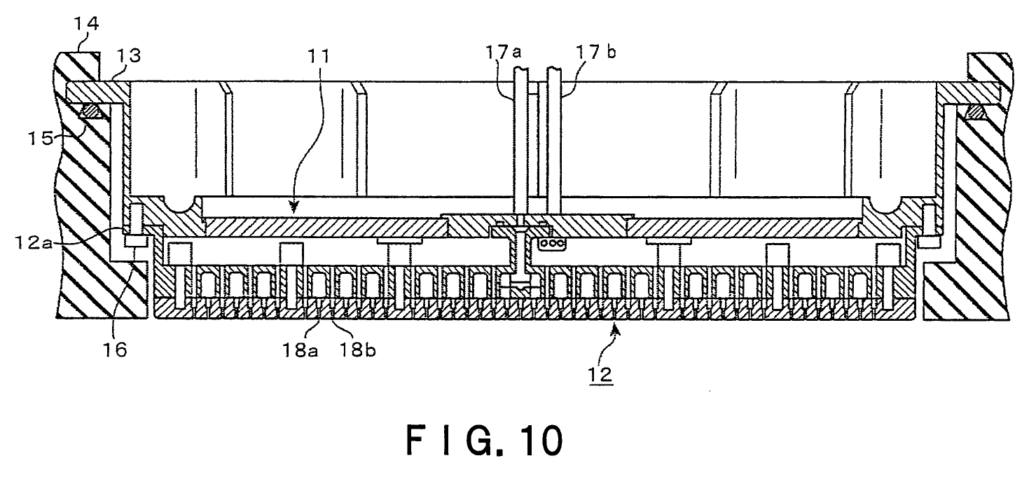

The gas showerhead according to the present invention is not limited to the pre-mix type, and may be of the conventional post-mix type as shown in FIG. 10. That is, the present invention can be applied to any apparatus in which a first gas and a second gas are separately supplied to the processing container 2.

Not limited to the Ti-film forming process, the present invention can be applied to any gas process such as a film forming process conducted at a high temperature for manufacturing a semiconductor device, including: a process for forming a film made out of a metal such as W, Cu, Ta, Ru, and Hf; a process for forming a film out of a metal compound such as TiN, TiSi, and WSi; and a process for forming a film out of an insulating material such as SiN and SiO₂, for example.

Moreover, not limited to the plasma CVD apparatus, the gas showerhead according to the present invention can be applied to other substrate processing apparatuses such as a thermal CVD apparatus, etching apparatus, ashing apparatus, spattering apparatus, and annealing apparatus.

In the above embodiment, although a semiconductor wafer is used as a substrate, an LCD substrate and a glass substrate may be used.

Furthermore, the joining portions of the nickel members are not limited to the above embodiment. For example, when the shower plate is formed by stacking two plates, an intermediate member may be interposed between their joining surfaces. That is, the present invention can be applied to any gas supplying unit formed by combining a plurality of nickel members.

1. A gas supplying unit to be arranged to hermetically fit in an opening formed at a ceiling part of a processing container for conducting a process to a substrate: the gas supplying unit comprising
a plurality of nickel members,
wherein
a large number of gas-supplying holes is formed at a lower surface of the gas supplying unit,
a process gas is adapted to be supplied from the large number of gas-supplying holes into the processing container, and
the plurality of nickel members is fixed to each other via an intermediate member for preventing sticking made of a material different from nickel.

2. A gas supplying unit to be arranged to hermetically fit in an opening formed at a ceiling part of a processing container for conducting a process to a substrate: the gas supplying unit comprising
a shower-plate mainly consisting of nickel, a large number of gas-supplying holes being formed in the shower-plate, and
a base member provided above the shower-plate in order to form a process-gas diffusion space between the base member and the shower-plate,
wherein
a portion of the base member opposite to the shower-plate is made mainly of nickel, and
an upper surface of a peripheral portion of the shower-plate and a lower surface of a peripheral portion of the base member are hermetically fixed to each other via an intermediate member for preventing sticking made of a material different from nickel.

3. A gas supplying unit according to claim 2, wherein
the base member is formed into a low and large cylindrical shape having a bottom,
an upper end of a peripheral side wall of the base member is hermetically attached to a peripheral portion of the opening of the processing container, and
a bottom surface of the peripheral side wall of the base member is hermetically fixed to a peripheral portion of the shower-plate.

4. A gas supplying unit according to claim 3, wherein
the peripheral side wall of the base member is made of a material having a lower thermal conductivity than nickel.

5. A gas supplying unit according to claim 4, wherein
the base member is provided with a reinforcement member made of a material having a lower thermal conductivity than nickel, in order to reinforce the peripheral side wall of the base member.

6. A gas supplying unit according to claim 4, wherein
the material having a lower thermal conductivity than nickel is hastelloy.

7. A gas supplying unit according to claim 3, wherein
a coolant way is formed at an upper-end portion of the peripheral side wall of the base member.

8. A gas supplying unit according to claim 7, wherein
an air is adapted to flow through the coolant way.

9. A gas supplying unit according to claim 2, wherein
a sheet-like heater is arranged on the base member via an insulating plate,
the insulating plate is divided into a plurality of insulating-plate elements in a planar direction thereof, and
the sheet-like heater is divided into a plurality of sheet-heater elements in a planar direction thereof.

10. A gas supplying unit according to claim 1, wherein
the intermediate member is made of hastelloy or carbon.

11. A gas supplying unit according to claim 2, wherein
the intermediate member is made of hastelloy or carbon.

12. A gas supplying unit according to claim 1, wherein
the process gas includes a first gas and a second gas,
the first gas and the second gas are capable of reacting on each other in order to generate a film-forming component,
the first gas and the second gas are mixed in advance to become a mixed gas, and
the mixed gas is supplied into the processing container as a process gas.

13. A gas supplying unit according to claim 2, wherein
the process gas includes a first gas and a second gas,
the first gas and the second gas are capable of reacting on each other in order to generate a film-forming component,
the first gas and the second gas are mixed in advance to become a mixed gas, and
the mixed gas is supplied into the processing container as a process gas.

14. A substrate processing apparatus comprising
a processing container whose ceiling part has an opening,
a stage provided in the processing container, for placing a substrate thereon,
a gas discharging unit for discharging a gas from the processing container, and
a gas supplying unit arranged to hermetically fit in the opening of the ceiling part of the processing container,
wherein
the gas supplying unit comprises a plurality of nickel members,
a large number of gas-supplying holes is formed at a lower surface of the gas supplying unit,
a process gas is adapted to be supplied from the large number of gas-supplying holes into the processing container, and
the plurality of nickel members is fixed to each other via an intermediate member for preventing sticking made of a material different from nickel.

15. A substrate processing apparatus comprising
a processing container whose ceiling part has an opening,
a stage provided in the processing container, for placing a substrate thereon,
a gas discharging unit for discharging a gas from the processing container, and
a gas supplying unit arranged to hermetically fit in the opening of the ceiling part of the processing container,
wherein
the gas supplying unit comprises: a shower-plate mainly consisting of nickel, a large number of gas-supplying holes being formed in the shower-plate; and a base member provided above the shower-plate in order to form a process-gas diffusion space between the base member and the shower-plate,
a portion of the base member opposite to the shower-plate is made mainly of nickel, and
an upper surface of a peripheral portion of the shower-plate and a lower surface of a peripheral portion of the base member are hermetically fixed to each other via an intermediate member for preventing sticking made of a material different from nickel.

16. A substrate processing apparatus according to claim 15, wherein
the base member is formed into a low and large cylindrical shape having a bottom,
an upper end of a peripheral side wall of the base member is hermetically attached to a peripheral portion of the opening of the processing container, and
a bottom surface of the peripheral side wall of the base member is hermetically fixed to a peripheral portion of the shower-plate.

17. A substrate processing apparatus according to claim 16, wherein
the upper end of the peripheral side wall of the base member is hermetically attached to the peripheral portion of the opening of the processing container via an upper-side insulating member made of alumina for radio-frequency insulation, and
a lower-side insulating member made of quartz for radio-frequency insulation is provided below the upper-side insulating member so as to cover a portion of the processing container located laterally adjacent to the peripheral side wall of the base member.

18. A substrate processing apparatus according to claim 16, wherein
the upper end of the peripheral side wall of the base member is hermetically attached to the peripheral portion of the opening of the processing container via a sealing member made of resin.

19. A substrate processing apparatus according to claim 14, further comprising
a first temperature-controlling unit provided in the stage for heating the substrate,
a second temperature-controlling unit provided in the gas supplying unit for controlling a temperature of a surface of the gas supplying unit in contact with the process gas, and
a controlling part that controls the first temperature-controlling unit and the second temperature-controlling unit,
wherein
a gas supplying control is adapted to be conducted in such a manner that: a titanium chloride gas and a hydrogen gas are supplied as a process gas from the gas supplying unit into the processing container in order to generate a titanium film on the substrate, and then an ammonia gas is supplied from the gas supplying unit into the processing container in order to nitride the titanium film on the substrate, and
the controlling part is adapted to control the second temperature-controlling unit in such a manner that: a temperature of the surface of the gas supplying unit in contact with the process gas is lower than a temperature at which nickel and ammonia react to generate a solid product, and is within a decomposition temperature zone of TiClx (x=1, 2 or 3).

20. A substrate processing apparatus according to claim 19, wherein
the controlling part is adapted to control the second temperature-controlling unit in such a manner that a temperature of the surface of the gas supplying unit in contact with the process gas is 400 to 450° C.

21. A substrate processing apparatus according to claim 19, wherein
the controlling part is adapted to control the first temperature-controlling unit in such a manner that a temperature of the substrate is increased to 450 to 600° C., and
the controlling part is adapted to control the second temperature-controlling unit in such a manner that a temperature of the second temperature-controlling unit is 180 to 475° C. depending on the temperature of the substrate.

22. A substrate processing apparatus according to claim 15, further comprising
a first temperature-controlling unit provided in the stage for heating the substrate,
a second temperature-controlling unit provided in the gas supplying unit for controlling a temperature of a surface of the gas supplying unit in contact with the process gas, and
a controlling part that controls the first temperature-controlling unit and the second temperature-controlling unit,
wherein
a gas supplying control is adapted to be conducted in such a manner that: a titanium chloride gas and a hydrogen gas are supplied as a process gas from the gas supplying unit into the processing container in order to generate a titanium film on the substrate, and then an ammonia gas is supplied as a process gas from the gas supplying unit into the processing container in order to nitride the titanium film on the substrate, and
the controlling part is adapted to control the second temperature-controlling unit in such a manner that: a temperature of the surface of the gas supplying unit in contact with the process gas is lower than a temperature at which nickel and ammonia react to generate a solid product, and is within a decomposition temperature zone of TiClx (x=1, 2 or 3).
